(19) United States
(12) Patent Application Publication
(10) Pub. No.: US 2024/0243550 A1
(43) Pub. Date: Jul. 18, 2024

(54) LASER ELEMENT AND ELECTRONIC DEVICE

(71) Applicant: SONY GROUP CORPORATION, TOKYO (JP)

(72) Inventors: KENJI TANAKA, TOKYO (JP); MASANAO KAMATA, TOKYO (JP)

(21) Appl. No.: 18/559,406

(22) PCT Filed: Feb. 15, 2022
(86) PCT No.: PCT/JP2022/005844

§ 371 Date: Nov. 7, 2023

(30) Foreign Application Priority Data
May 26, 2021 (JP) 2021-088687

(51) Int. Cl. H01S 5/183; H01S 3/0941; H01S 3/10; H01S 3/113; H01S 3/16; H01S 5/343

(52) U.S. Cl. CPC H01S 5/18305; H01S 3/09415; H01S 3/10053; H01S 3/10061; H01S 3/113; H01S 3/1618; H01S 3/1643; H01S 5/34313

(57) ABSTRACT

Provided is a laser element capable of integrating a plurality of optical elements and inhibiting a standing wave of excitation light or oscillation light. A laser element includes: a laminated semiconductor layer including a first reflection layer and an active layer that performs surface emission at a first wavelength; a laser medium including a second reflection layer on a first surface and a third reflection layer on a second surface; a fourth reflection layer disposed on the rear side of the optical axis with respect to the second surface; a first resonator that causes light of the first wavelength to resonate between the first reflection layer and the third reflection layer; a second resonator that causes light of a second wavelength to resonate between the second reflection layer and the fourth reflection layer; a first polarization conversion element provided between the first reflection layer and the laser medium; a second polarization conversion element provided between the second reflection layer and the laser medium, and at least one of first or second polarization control element provided between the first reflection layer and the fourth reflection layer. The optical axis of the laminated semiconductor layer, an optical axis of the laser medium, and optical axes of the first and second polarization conversion elements and the first or second polarization control element are coaxially arranged.

### TECHNICAL FIELD

The present disclosure relates to a laser element and an electronic device.

### BACKGROUND ART

The peak power of a laser is defined as the pulse energy divided by the pulse width, and in order to achieve higher peak power, it is important to obtain a shorter pulse width. A Q-switched solid-state laser that outputs a laser pulse has a feature that the length of its own resonator is proportional to the obtained pulse width, and the minimum resonator length is affected by the length of the used solid-state laser medium. On the other hand, the length of the solid-state laser medium installed in the resonator as a gain medium is determined by the amount of excitation light absorbed. Thus, when the length of the solid-state laser medium is simply reduced, the excitation light cannot be sufficiently absorbed, leading to a significant decrease in excitation efficiency.

Therefore, in the conventional method of externally exciting a Q-switched solid-state laser medium with a semiconductor laser, it is not preferable to make the length of the solid-state laser medium shorter than the absorption length of excitation light, and a shorter pulse cannot be obtained. That is, reducing the length of the solid-state laser medium in order to obtain a short pulse width leads to a decrease in the amount of excitation light absorbed and a decrease in excitation efficiency. In contrast, increasing the length of the solid-state laser medium in order to increase the amount of excitation light absorbed leads to a longer resonator length and an extended pulse width, and hence such a trade-off exists in the conventional method.

Meanwhile, in terms of manufacturing and the stability of light source output, the conventional Q-switched solid-state laser requires assembly adjustment by high-precision positioning of a plurality of optical elements, thus reducing mass productivity and making cost reduction difficult, and also posing challenges in the stability light source output due to positional displacement of each optical element. Therefore, it is conceivable to integrate a plurality of optical elements.

In the integration of the optical element, a configuration in which the solid-state laser medium is shared by the resonator of the excitation light and the resonator of the oscillation light is conceivable. However, in this case, the excitation light or the oscillation light for exciting the solid-state laser medium resonates in each resonator, and may become a standing wave in the solid-state laser medium. This causes a decrease in excitation efficiency and stability in the solid-state laser medium.

### CITATION LIST

### Patent Document

Patent Document 1: Japanese Patent Application Laid-Open No. 2013-219232
Patent Document 2: Japanese Patent Application Laid-Open No. 2019-176119
Patent Document 3: Japanese Patent Application Laid-Open No. 2007-173393
Patent Document 4: International Publication No. WO 2019/049694

### SUMMARY OF THE INVENTION

### Problems to be Solved by the Invention

Therefore, the present disclosure provides a laser element capable of inhibiting a standing wave of excitation light or oscillation light while integrating a plurality of optical elements.

### Solutions to Problems

A laser element according to one aspect of the present disclosure includes: a laminated semiconductor layer including a first reflection layer with respect to a first wavelength and an active layer that performs surface emission at the first wavelength; a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface opposite to the first surface; a fourth reflection layer with respect to the second wavelength, the forth reflection layer being disposed on the second surface or disposed on a rear side of the optical axis with respect to the second surface; a first resonator that causes light of the first wavelength to resonate between the first reflection layer and the third reflection layer; a second resonator that causes light of the second wavelength to resonate between the second reflection layer and the fourth reflection layer; a first polarization conversion element that is provided between the first reflection layer and the laser medium, and causes a phase difference for light in vibration directions orthogonal to each other in the light of the first wavelength or the light of the second wavelength; a second polarization conversion element that is provided between the second reflection layer and the laser medium, and causes a phase difference for light in vibration directions orthogonal to each other in the light of the first wavelength or the light of the second wavelength; and at least one of a first polarization control element or a second polarization control element that is provided between the first reflection layer and the fourth reflection layer, and controls polarization of the light of the first wavelength or the light of the second wavelength. The optical axis of the laminated semiconductor layer, an optical axis of the laser medium, and optical axes of the first polarization conversion element, the second polarization conversion element, and the first polarization control element or the second polarization control element are coaxially arranged.

An anisotropic material, a meta-surface structure, or a photonic crystal structure is used for the first polarization conversion element and the second polarization conversion element.

Each of the first polarization conversion element and the second polarization conversion element provides a phase difference of about one-quarter wavelength for light in vibration directions orthogonal to each other in the light of the first or second wavelength.

A fifth reflection layer provided on the laser medium side of the laminated semiconductor layer is further provided.

The first polarization control element is provided between the first reflection layer and the first polarization conversion element, and controls polarization of the light of the first wavelength.

The second polarization control element is provided between the fourth reflection layer and the second polarization conversion element, and controls polarization of light of the second wavelength.

The first polarization control element has a fine structure on a surface so as to have different transmittances for polarized light orthogonal to each other among the light of the first wavelength.

The second polarization control element has a fine structure on a surface so as to have different transmittances for polarized light orthogonal to each other among the light of the second wavelength.

A saturable absorber provided between the third reflection layer and the fourth reflection layer is further provided.

The first polarization conversion element is disposed between the first polarization control element and the second reflection layer, and the second polarization conversion element is disposed between the laser medium and the third reflection layer.

The first polarization conversion element is disposed between the second reflection layer and the laser medium, and the second polarization conversion element is disposed between the third reflection layer and the second polarization control element.

The first polarization conversion element is disposed between the second reflection layer and the laser medium, and the second polarization conversion element is disposed between the laser medium and the third reflection layer.

The fourth reflection layer has a fine structure on a surface so as to have different transmittances for polarized light orthogonal to each other among the light of the second wavelength.

The saturable absorber has a fine structure on a surface so as to have different transmittances for polarized light orthogonal to each other among the light of the second wavelength.

The fourth reflection layer causes a phase difference for light in vibration directions orthogonal to each other in the light of the second wavelength.

The first polarization control element is provided between the second reflection layer and the first polarization conversion element, and the first polarization control element has a fine structure on a surface so as to have different transmittances for polarized light orthogonal to each other among the light of the first wavelength and have different transmittances for polarized light orthogonal to each other among the light of the second wavelength.

The second polarization control element is provided between the third reflection layer and the second polarization conversion element, and the second polarization control element has a fine structure on a surface so as to have different transmittances for polarized light orthogonal to each other among the light of the first wavelength and have different transmittances for polarized light orthogonal to each other among the light of the second wavelength.

The first polarization conversion element has a fine structure on a surface so as to have different transmittances for polarized light orthogonal to each other among the light of the first wavelength.

The second polarization conversion element has a fine structure on a surface so as to have different transmittances for polarized light orthogonal to each other among the light of the second wavelength.

The laminated semiconductor layer, the laser medium, the fourth reflection layer, the first resonator, the second resonator, the first polarization conversion element, the second polarization conversion element, and the first polarization control element or the second polarization control element are integrally bonded.

A transparent member provided at any position between the first reflection layer and the fourth reflection layer is further provided.

An electronic device according to one aspect of the present disclosure includes: a laser element; and a control unit that performs control to emit light from the laser element. The laser element includes a laminated semiconductor layer including a first reflection layer with respect to a first wavelength and an active layer that performs surface emission at the first wavelength, a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface opposite to the first surface, a fourth reflection layer with respect to the second wavelength, the forth reflection layer being disposed on the second surface or disposed on a rear side of the optical axis with respect to the second surface, a first resonator that causes light of the first wavelength to resonate between the first reflection layer and the third reflection layer, a second resonator that causes light of the second wavelength to resonate between the second reflection layer and the fourth reflection layer, a first polarization conversion element that is provided between the first reflection layer and the laser medium, and causes a phase difference for light in vibration directions orthogonal to each other in the light of the first wavelength, a second polarization conversion element that is provided between the second reflection layer and the laser medium, and causes a phase difference for light in vibration directions orthogonal to each other in the light of the second wavelength, and at least one of a first polarization control element or a second polarization control element that is provided between the first reflection layer and the fourth reflection layer, and controls polarization of the light of the first wavelength or the light of the second wavelength. The optical axis of the laminated semiconductor layer, an optical axis of the laser medium, and optical axes of the first polarization conversion element, the second polarization conversion element, and the first polarization control element or the second polarization control element are coaxially arranged.

### BRIEF DESCRIPTION OF DRAWINGS

FIG. 1 is a diagram illustrating a basic configuration of a laser element according to the present disclosure.

FIG. 2A is a cross-sectional view illustrating a configuration example of a laser element according to a first embodiment.

FIG. 2B is a cross-sectional view illustrating a configuration example of a laser element including a transparent member.

FIG. 3 is a cross-sectional view illustrating a configuration example of a laser element according to a second embodiment.

FIG. 4 is a cross-sectional view illustrating a configuration example of a laser element according to a third embodiment.

FIG. 5 is a cross-sectional view illustrating a configuration example of a laser element according to a fourth embodiment.

FIG. 6 is a cross-sectional view illustrating a configuration example of a laser element according to a fifth embodiment.

FIG. 7 is a cross-sectional view illustrating a configuration example of a laser element according to a sixth embodiment.

FIG. 8 is a cross-sectional view illustrating a configuration example of a laser element according to a seventh embodiment.

FIG. 9 is a cross-sectional view illustrating a configuration example of a laser element according to an eighth embodiment.

FIG. 10 is a cross-sectional view illustrating a configuration example of a laser element according to a ninth embodiment.

FIG. 11 is a cross-sectional view illustrating a configuration example of a laser element according to a tenth embodiment.

FIG. 12 is a cross-sectional view illustrating a configuration example of a laser element according to an eleventh embodiment.

FIG. 13 is a cross-sectional view illustrating a configuration example of a laser element according to a twelfth embodiment.

FIG. 14 is a cross-sectional view illustrating a configuration example of a laser element according to a thirteenth embodiment.

FIG. 15 is a diagram illustrating an example of a schematic configuration of an endoscope system.

FIG. 16 is a block diagram illustrating an example of a functional configuration of a camera and a camera control unit (CCU) illustrated in FIG. 15.

FIG. 17 is a diagram illustrating an example of a schematic configuration of a microscopic surgery system.

### MODE FOR CARRYING OUT THE INVENTION

Hereinafter, specific embodiments to which the present technology is applied will be described in detail with reference to the drawings. The drawings are schematic or conceptual, and the ratio of each part and the like are not necessarily the same as actual ones. In the specification and the drawings, similar elements as those described above with respect to the previously described drawings are denoted by the same reference numerals, and the detailed description thereof is appropriately omitted.

(Technical Features of Laser Element according to Present Disclosure)

First, technical features of a laser element according to the present disclosure will be described before descriptions of an internal configuration and an operation of the laser element according to the present disclosure.

A laser element according to the present disclosure has a configuration in which a structure using a part of a surface-emitting laser as a light emitting element and a solid-state laser medium for Q-switching are integrally bonded. Note that, as described later, the laser element according to the present disclosure may include a laser element not having a Q-switching function, but a laser element having the Q-switching function will be first described.

In the laser element according to the present disclosure, the solid-state laser medium for Q-switching is shared by two resonators. These two resonators include a first resonator that resonates at a first wavelength and a second resonator (also referred to as a Q-switched solid-state laser resonator) that resonates at a second wavelength.

Since the two resonators share the solid-state laser medium, high-intensity excitation of the solid-state laser medium can be performed in the first resonator even when the solid-state laser medium is reduced, and a laser pulse having a shorter pulse width can be generated.

Furthermore, the laser element according to the present disclosure is an integrated laminated structure that can be fabricated by using a semiconductor process technology, and is thus excellent in mass productivity as well as laser output stability.

Here, the light emitting element is a form of a surface-emitting laser (vertical cavity surface-emitting laser (VCSEL)). This is different from the VCSEL in that at least one of mirrors forming the resonator is provided outside a laminated semiconductor layer, which is a main body of the light emitting element. As described later, the laser element according to the present disclosure has a structure in which the solid-state laser medium is disposed between the laminated semiconductor layer and the mirror disposed outside the laminated semiconductor layer.

As described above, by integrating the plurality of optical elements in the laser element, the laser element can generate a laser pulse having a short pulse width by Q-switching. Here, in the integration of the optical element, a configuration in which the solid-state laser medium is shared by the resonator of the excitation light and the resonator of the oscillation light is conceivable. However, in this case, the excitation light or the oscillation light for exciting the solid-state laser medium resonates in each resonator, and becomes a standing wave in the solid-state laser medium. The standing wave of the excitation light does not excite the solid-state laser medium in the section, and reduces the excitation efficiency. Moreover, the standing wave of the excitation light causes re-absorption of the oscillation light in the solid-state laser medium. The standing wave of the oscillation light causes a so-called spatial hole burning phenomenon.

Therefore, in the laser element according to the present disclosure, polarization conversion elements are provided on both sides of the solid-state laser medium to cause a phase difference for light in vibration directions orthogonal to each other in the excitation light or the oscillation light, and a polarization control element is provided to cause laser oscillation of only polarized light in one direction. This makes it possible to inhibit the generation of the standing wave of the excitation light or the oscillation light without impairing the advantage of the small integrated structure.

The laser element according to the present disclosure has the following three features.
(1) The first resonator and the second resonator share the solid-state laser medium. The first resonator includes a light emitting element and a solid-state laser medium. The second resonator includes the solid-state laser medium and a saturable absorber, and performs Q-switched laser oscillation using excitation light from the first resonator.
(2) Polarization conversion elements that cause a phase difference for light in vibration directions orthogonal to each other in the excitation light and/or the oscillation light are provided on both sides of the solid-state laser medium. Moreover, at least one polarization control element for controlling polarization in one direction is provided in the resonator between the polarization conversion element and the reflection layer on the side opposite to solid-state laser medium. The polarization conversion element and the polarization control element inhibit the standing wave of the excitation light and/or the oscillation light in the solid-state laser medium.
(3) The light emitting element, the solid-state laser medium, and the saturable absorber have an integrated structure.

In the laser element according to the present disclosure, the solid-state laser medium in the first resonator absorbs the excitation light generated by injecting a current into the light emitting element. The solid-state laser medium forms the second resonator together with the saturable absorber installed in the first resonator. When the solid-state laser medium comes into a sufficiently excited state, and an output of spontaneous emission light increases above a certain threshold, a light absorption rate in the saturable absorber rapidly decreases, and the spontaneous emission light generated in the solid-state laser medium can be transmitted through the saturable absorber, causing induced emission in the solid-state laser medium. This results in Q-switched pulse oscillation.

### (Basic Configuration of Laser Element)

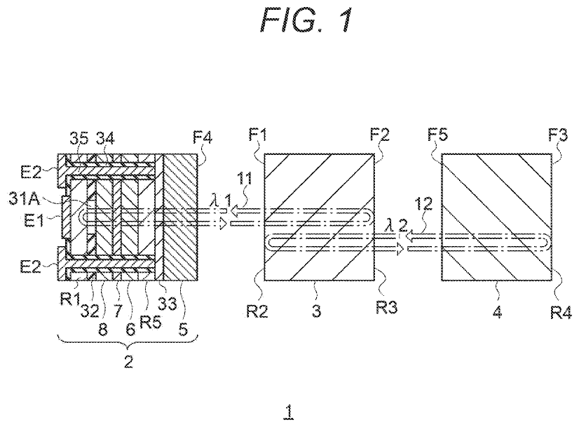

A specific embodiment of the laser element according to the present disclosure will be described below. FIG. 1 is a diagram illustrating a basic configuration of a laser element 1 according to the present disclosure. The laser element 1 of FIG. 1 has a configuration in which a light emitting element 2, a solid-state laser medium 3, and a saturable absorber 4 are integrally bonded.

The light emitting element 2 includes a semiconductor layer (laminated semiconductor layer) having a laminated structure. The light emitting element 2 of FIG. 1 has a structure in which a substrate 5, a fifth reflection layer R5, a cladding layer 6, an active layer 7, a cladding layer 8, and a first reflection layer R1 are sequentially laminated. Note that the laser element 1 of FIG. 1 has a bottom emission type configuration in which continuous wave (CW) excitation light is emitted from the substrate 5, but may have a top emission type configuration in which the CW excitation light is emitted from the first reflection layer R1 side.

The substrate 5 is, for example, an n-GaAs substrate 5. The n-GaAs substrate 5 absorbs light of a first wavelength A1, which is the excitation wavelength of the light emitting element 2, at a certain rate, and it is thus desirable to make the n-GaAs substrate 5 as thin as possible. In contrast, it is desirable to provide such a degree of thickness that can maintain mechanical strength at the time of a bonding process to be described later.

The active layer 7 performs surface emission at the first wavelength λ1. The cladding layers 6, 8 are, for example, AlGaAs cladding layers. The first reflection layer R1 reflects the light of the first wavelength λ1. The fifth reflection layer R5 has a certain transmittance with respect to the light of the first wavelength λ1. For the first reflection layer R1 and the fifth reflection layer R5, for example, a semiconductor distributed Bragg reflector (DBR) capable of performing electrical conduction is used. A current is externally injected via the first reflection layer R1 and the fifth reflection layer R5, recombination and light emission occur in a quantum well in the active layer 7, and laser oscillation at the first wavelength λ1 is performed. A part of the surface layer (e.g., AlAs layer) 31A on the cladding layer side of the first reflection layer R1 is oxidized to become an oxide layer (e.g., Al₂O₃ layer) 32.

The fifth reflection layer R5 is provided on the solid-state laser medium 3 side of the light emitting element 2, and is provided between the semiconductor layer of the light emitting element 2 and the solid-state laser medium 3. The fifth reflection layer R5 is disposed on, for example, the n-GaAs substrate 5. For example, the fifth reflection layer R5 includes a multilayer reflection film containing Al_{z1}Ga_{1-z1}As/Al_{z2}Ga_{1-z2}As (0≤z1≤z2≤1) to which an n-type dopant (e.g., silicon) is added. The fifth reflection layer R5 is also referred to as an n-DBR. More specifically, the n-contact layer 33 is disposed between the fifth reflection layer R5 and the n-GaAs substrate 5.

The active layer 7 includes, for example, a multiple quantum well layer in which an Alₓ₁In_{y1}Ga_{1-x1-y1}As layer and an Alₓ₃In_{y3}Ga_{1-x3-y3}As layer are laminated.

The first reflection layer R1 includes, for example, a multiple reflection film formed by Al_{z3}Ga_{1-z3}As/Al_{z4}Ga_{1-z4}As (0≤z3≤z4≤1) to which a p-type dopant (e.g., carbon) is added. The first reflection layer R1 is also referred to as a p-DBR.

Each of the semiconductor layers R5, 6, 7, 8, R1 in the light emitting element 2 can be formed by using a crystal growth method such as a metal-organic chemical vapor deposition (MOCVD) method or a molecular beam epitaxy (MBE) method. Then, after the crystal growth, driving by current injection becomes possible after processes such as mesa etching for element separation, formation of an insulating film, and vapor deposition of an electrode film.

The solid-state laser medium 3 is bonded to the end face on the side opposite to the fifth reflection layer R5 of the n-GaAs substrate 5 of the light emitting element 2. Hereinafter, the end face on the light emitting element 2 side of the solid-state laser medium 3 is referred to as a first surface F1, and the end face on the saturable absorber 4 side of the solid-state laser medium 3 is referred to as a second surface F2. Furthermore, a laser pulse emission surface of the saturable absorber 4 is referred to as a third surface F3, and the end face on the solid-state laser medium 3 side of the light emitting element 2 is referred to as a fourth surface F4. Furthermore, the end face on the solid-state laser medium 3 side of the saturable absorber 4 is referred to as a fifth surface F5. Although illustrated separately for convenience in FIG. 1, the fourth surface F4 of the light emitting element 2 is bonded to the first surface F1 of the solid-state laser medium 3, and the second surface F2 of the solid-state laser medium 3 is bonded to the fifth surface F5 of the saturable absorber 4.

The laser element 1 of FIG. 1 includes a first resonator 11 and a second resonator 12. The first resonator 11 causes the light of the first wavelength A1 to resonate between the first reflection layer R1 in the light emitting element 2 and a third reflection layer R3 in the solid-state laser medium 3. The second resonator 12 causes light of a second wavelength λ2 to resonate between a second reflection layer R2 in the solid-state laser medium 3 and a fourth reflection layer R4 in the saturable absorber 4.

The second resonator 12 is also referred to as a Q-switched solid-state laser resonator 12. A third reflection layer R3, which is a high reflection layer, is provided in the solid-state laser medium 3 so that the first resonator 11 can perform a stable resonance operation. In the normal light emitting element 2, a partially reflecting mirror for emitting the light of the first wavelength λ1 to the outside is disposed at a position of the third reflection layer R3 in FIG. 1. In contrast, in the laser element 1 of FIG. 1, the high reflection layer is used as the third reflection layer R3 in order to use the third reflection layer R3 for confining power of the excitation light of the first wavelength λ1 in the first resonator 11.

In this manner, three reflection layers (first reflection layer R1, fifth reflection layer R5, and third reflection layer R3) are provided inside the first resonator 11 including the light emitting element 2 and the solid-state laser medium 3. Therefore, the first resonator 11 has a coupled resonator (coupled cavity) structure.

The solid-state laser medium 3 is excited by confining the power of the excitation light of the first wavelength λ1 in the first resonator 11. Therefore, Q-switched laser pulse oscillation occurs in the second resonator 12. The second resonator 12 causes light of a second wavelength λ2 to resonate between a second reflection layer R2 in the solid-state laser medium 3 and a fourth reflection layer R4 in the saturable absorber 4. The second reflection layer R2 is a high reflection layer, whereas the fourth reflection layer R4 is a partial reflection layer. In FIG. 1, the fourth reflection layer R4 is provided on the end face of the saturable absorber 4, but the fourth reflection layer R4 may be disposed on a rear side of an optical axis with respect to the laser pulse emission surface of the saturable absorber 4. The rear side of the optical axis is in a light emission direction on the optical axis. That is, the fourth reflection layer R4 is not necessarily provided inside or on the surface of the saturable absorber 4. However, even in a case where the fourth reflection layer R4 is disposed on the front side of the optical axis with respect to the saturable absorber 4, it is necessary to cause the light of the second wavelength λ2 to resonate between the second reflection layer R2 and the fourth reflection layer R4.

The solid-state laser medium 3 contains, for example, ytterbium (Yb)-doped yttrium aluminum garnet (YAG) crystal Yb:YAG. In this case, the first wavelength λ1 of the first resonator 11 is 940 nm, and the second wavelength λ2 of the second resonator 12 is 1030 nm.

The solid-state laser medium 3 is not limited to Yb:YAG, and for example, at least any material of Nd:YAG, Nd:YVO4, Nd:YLF, Nd:glass, Yb:YAG, Yb:YLF, Yb:FAP, Yb:SFAP, Yb:YVO, Yb:glass, Yb:KYW, Yb:BCBF, Yb:YCOB, Yb:GdCOB, and YB:YAB can be used as the solid-state laser medium 3.

Furthermore, the solid-state laser medium 3 may be a four-level system solid-state laser medium 3 or a quasi-three-level system solid-state laser medium 3. However, since an appropriate excitation wavelength (first wavelength λ1) varies depending on each crystal, it is necessary to select the semiconductor material of the active layer 7 in the light emitting element 2 according to the material of the solid-state laser medium 3.

The saturable absorber 4 contains, for example, a chromium (Cr)-doped YAG (Cr:YAG) crystal. The saturable absorber 4 is a material in which the transmittance increases when the intensity of incident light exceeds a predetermined threshold. The excitation light of the first wavelength λ1 by the first resonator 11 increases the transmittance of the saturable absorber 4 to emit the laser pulse of the second wavelength λ2. This is referred to as a Q-switch. As the material of the saturable absorber 4, V:YAG can also be used. However, other types of saturable absorber 4 may also be used. Furthermore, the use of an active Q-switched element as the Q-switch is not prevented.

In FIG. 1, the light emitting element 2, the solid-state laser medium 3, and the saturable absorber 4 are separately illustrated, but they are bonded to be integrated by using a bonding process to form a laminated structure. Examples of the bonding process include surface activation bonding, atomic diffusion bonding, plasma activation bonding, and the like. Alternatively, other bonding (adhering) processes can be used.

To stably bond the solid-state laser medium 3 to the light emitting element 2, it is necessary to flatten the surface of the n-GaAs substrate 5 in the light emitting element 2. Therefore, as described above, it is desirable that electrodes E1, E2 for injecting a current into the first reflection layer R1 and the fifth reflection layer R5 be arranged so as not to be exposed at least on the surface of the n-GaAs substrate 5. In the example in FIG. 1, the electrodes E1, E2 are arranged on the end face on the first reflection layer R1 side of the light emitting element 2. The electrode E1 is a p-electrode, and is electrically conducted with the first reflection layer R1. The electrode E2 is an n-electrode, and is formed by filling an inner wall of a trench reaching the n-contact layer 33 from the first reflection layer R1 with a conductive material 35 via an insulating film 34. Arranging the electrodes E1, E2 on the same end face of the light emitting element 2 as in FIG. 1 enables this end face to be soldered to a support substrate (not illustrated). Also, when a plurality of laser elements is arranged in an array, arranging the electrodes E1, E2 on the same end face enables this end face to be mounted on the support substrate. Note that the shapes and arranged positions of the electrodes E1, E2 illustrated in FIG. 1 are illustrative only.

In this manner, forming the laser element 1 of FIG. 1 into a laminated structure facilitates formation of a plurality of chips by dicing the laminated structure to separate after fabricating the same, or formation of a laser array in which a plurality of laser elements 1 is arranged in an array on one substrate.

In a case where the laser element 1 having the laminated structure is fabricated by the bonding process, arithmetic average roughness Ra of each surface layer needs to be about 1 nm or less, and is desirably 0.5 nm or less. Chemical mechanical polishing (CMP) is used to implement the surface layer having such arithmetic average roughness. Furthermore, in order to avoid an optical loss at the interface of each layer, a dielectric multilayer film may be disposed between the layers, and the layers may be bonded via the dielectric multilayer film. For example, the GaAs substrate 5 as the base substrate of the light emitting element 2 has a refractive index n of 3.2 with respect to a wavelength of 940 nm, which is higher than that of YAG (n:1.7) or a general dielectric multilayer film material. Therefore, when the solid-state laser medium 3 and the saturable absorber 4 are bonded to the light emitting element 2, it is necessary to prevent optical loss due to refractive index mismatch from occurring. Specifically, it is desirable to dispose an anti-reflection film (AR coating film or non-reflection coating film) that does not reflect the light of the first wavelength λ1 of the first resonator 11 between the light emitting element 2 and the solid-state laser medium 3. Furthermore, it is desirable to arrange an anti-reflection film (AR coating film or non-reflection coating film) also between the solid-state laser medium 3 and the saturable absorber 4.

Polishing is sometimes difficult depending on a bonding material, and for example, a material that is transparent with respect to the first wavelength λ1 and the second wavelength λ2, such as SiO₂, may be deposited as a base layer for bonding, and this SiO₂ layer may be polished to have arithmetic average roughness Ra of about 1 nm (preferably 0.5 nm or less) and used as an interface for bonding. Here, a material other than SiO₂ can be used as the base layer, and the material is not limited. Note that a non-reflection film may be provided between SiO₂ as the material of the base layer and a base material layer.

Examples of the dielectric multilayer film include a short-wave pass filter (SWPF), a long-wave pass filter (LWPF), a band pass filter (BPF), an anti-reflection (AR) protective film, and the like. It is desirable to arrange different types of dielectric multilayer films as necessary. A physical vapor deposition (PVD) method can be used as a film deposition method for the dielectric multilayer film, and specifically, a film deposition method such as vacuum vapor deposition, ion-assisted vapor deposition, and sputtering can be used. Which film deposition method is applied is not limited. Furthermore, any characteristic of the dielectric multilayer film can be selected, and for example, the second reflection layer R2 may be a short-wave pass filter, and the third reflection layer R3 may be a long-wave pass filter. Furthermore, applying the long-wave pass filter to the third reflection layer R3 makes it possible to prevent the first wavelength from entering the saturable absorber and to prevent malfunction of the Q-switch. Note that the short-wave pass means that the light of the first wavelength λ1 is transmitted and the light of the second wavelength λ2 is reflected. Furthermore, the long-wave pass means that the light of the first wavelength λ1 is reflected and the light of the second wavelength λ2 is transmitted.

Furthermore, a polarizer having a photonic crystal structure that separates a ratio of P-polarized light and S-polarized light may be provided inside the second resonator 12. Furthermore, it is possible to provide a diffraction grating inside the second resonator 12 to convert the polarization state of the emitted laser pulse from random polarization to linear polarization.

### (Operation Principle of Laser Element 1)

Next, the operation of the laser element 1 of FIG. 1 will be described. By injecting a current into the active layer 7 via the electrode of the light emitting element 2, laser oscillation at the first wavelength λ1 occurs in the first resonator 11, and the solid-state laser medium 3 is excited. Since the saturable absorber 4 is bonded to the solid-state laser medium 3, in an initial stage when the laser oscillation at the first wavelength λ1 occurs, the spontaneous emission light from the solid-state laser medium 3 is absorbed by the saturable absorber 4, so that optical feedback by the fourth reflection layer R4 on the emission surface side of the saturable absorber 4 does not occur, and the Q-switched laser oscillation does not occur.

Thereafter, when the power of the excitation light of the first wavelength λ1 is accumulated in the solid-state laser medium 3, and the solid-state laser medium 3 comes into a sufficiently excited state, the output of the spontaneous emission light increase. When this exceeds a certain threshold, a light absorption rate in the saturable absorber 4 rapidly decreases, enabling the spontaneous emission light generated in the solid-state laser medium 3 to be transmitted through the saturable absorber 4. Therefore, the light of the first wavelength λ1 by the first resonator 11 is emitted from the solid-state laser medium 3, and the second resonator 12 causes the light of the second wavelength λ2 to resonate between the second reflection layer R2 and the fourth reflection layer R4. Therefore, the Q-switched laser oscillation occurs, and the Q-switched laser pulse is emitted toward a space (space on the right side in FIG. 1) via the fourth reflection layer R4.

A non-linear optical crystal for wavelength conversion can be disposed inside the second resonator 12. The wavelength of the laser pulse after the wavelength conversion can be changed depending on the type of the non-linear optical crystal. Examples of wavelength converting materials include non-linear optical crystals such as LiNbO₃, BBO, LBO, CLBO, BiBO, KTP, and SLT. Furthermore, a phase-matching material similar to these materials may be used as the wavelength converting material. Note that the type of the wavelength converting material is not limited. The second wavelength λ2 can be converted to another wavelength using the wavelength converting material.

The basic configuration and the operation principle for obtaining the Q-switched laser oscillation according to the present disclosure have been described above. Next, embodiments of a laser element according to the present disclosure will be described.

### First Embodiment

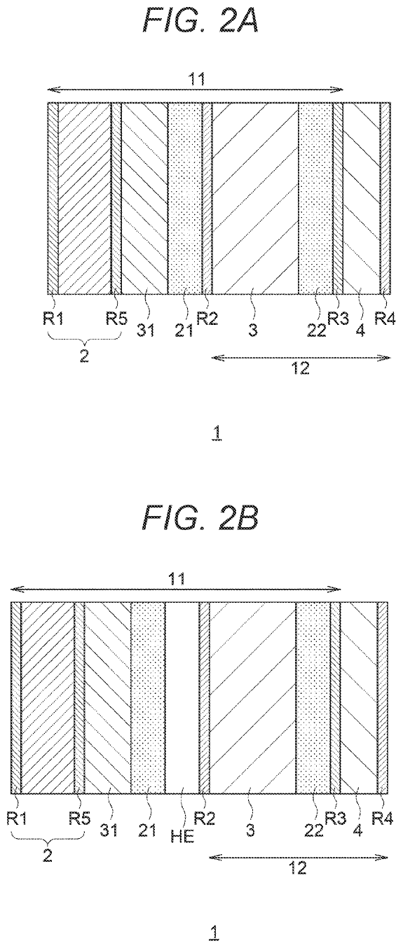

FIG. 2A is a cross-sectional view illustrating a configuration example of a laser element 1 according to a first embodiment. The laser element 1 further includes polarization conversion elements 21, 22 and a polarization control element 31 with respect to the basic configuration of FIG. 1. The saturable absorber 4 is disposed between the third reflection layer R3 and the fourth reflection layer R4. Note that, in the embodiment of the present specification, the optical elements (e.g., the light emitting element 2, the solid-state laser medium 3, the reflection layers R1 to R5, the resonators 11, 12, the polarization conversion elements 21, 22, and the polarization control element 31) forming the laser element 1 are integrally bonded.

The polarization conversion element 21 as the first polarization conversion element is disposed on the optical axis of the excitation-light resonator 11 at any position between the first reflection layer R1 and the solid-state laser medium 3 in the excitation-light resonator 11. More specifically, the polarization conversion element 21 is provided between the polarization control element 31 and the second reflection layer R2. The polarization conversion element 21 causes a phase difference for light in vibration directions orthogonal to each other in the excitation light of the first wavelength.

The polarization conversion element 22 as the second polarization conversion element is disposed on the side opposite to the solid-state laser medium 3 with respect to the polarization conversion element 21. The polarization conversion element 22 is disposed on the optical axis of the excitation-light resonator 11 at any position between the fourth reflection layer R4 and the solid-state laser medium 3. More specifically, the polarization conversion element 22 is provided between the third reflection layer R3 and the solid-state laser medium 3. The polarization conversion element 22 causes a phase difference for light in vibration directions orthogonal to each other in the excitation light of the first wavelength. In this manner, the two polarization conversion elements 21, 22 are disposed on both sides of the solid-state laser medium 3.

The polarization conversion elements 21, 22 each provide a different phase difference to the light in vibration directions orthogonal to each other in the excitation light. For example, the polarization conversion elements 21, 22 each provide a phase difference of about one-quarter wavelength (That is, π/2) between a transverse magnetic (TM) wave and a Transverse Electric (TE) wave of the excitation light. At this time, the principal axes of the polarization conversion elements 21, 22 are perpendicular to each other and inclined at a 45-degree angle relative to a polarization direction defined by the polarization control element 31. Note that the phase difference provided to the excitation light by each of the polarization conversion elements 21, 22 is not necessarily one-quarter wavelength. For the polarization conversion elements 21, 22, for example, an anisotropic material, a meta-surface structure, a photonic crystal structure, or the like is used.

As described above, since the polarization conversion elements 21, 22 provide different phase differences to the light in the vibration directions orthogonal to each other in the excitation light, the excitation light does not become a standing wave in the solid-state laser medium 3, and the solid-state laser medium 3 can be efficiently excited. In the present embodiment, the polarization conversion elements 21, 22 act on the excitation light but do not act on the oscillation light of the second wavelength λ2. However, the polarization conversion elements 21, 22 may act on the oscillation light as described later.

The polarization control element 31 as the first polarization control element is provided at any position between the first reflection layer R1 and the fourth reflection layer R4 or the polarization conversion element 21. More specifically, the polarization control element 31 is provided between the substrate 5 of the light emitting element 2 and the polarization conversion element 21, and is disposed on the optical axis of the excitation-light resonator 11. The polarization control element 31 controls the polarization of the excitation light of the first wavelength λ1. For the polarization control element 31, for example, a dielectric (e.g., Al₂O₃, SiO₂, Ta₂O₅, and HfO₂), a semiconductor (e.g., GaN, InN, AlN), or the like is used, and a material transparent to excitation light is used. Although not illustrated, a grating structure as a fine structure is formed on the surface of the polarization control element 31. As a result, the polarization control element 31 has different transmittances for polarized light (TM wave, TE wave) orthogonal to each other among the excitation light of the first wavelength λ1. The grating structure may be, for example, an uneven structure having a period equal to or less than the first wavelength λ1 of the excitation light and having a depth equal to or less than a quarter of the first wavelength λ1 of the excitation light. The grating structure may be, for example, a one-dimensional surface relief grating structure using 0th-order diffracted light (transmitted light). That is, the pattern of the grating structure may be a so-called line-and-space pattern. As a result, the polarization control element 31 has different transmittances for polarized light (TM wave, TE wave) orthogonal to each other among the 0th-order diffracted light (transmitted light) of the excitation light. Furthermore, the polarization of the excitation light is controlled in one direction instead of being randomly polarized by the polarization control element 31, so that it is possible to improve the characteristics of the excitation-light resonator 11, which includes stabilizing the oscillation output and improving wavelength conversion efficiency Note that the polarization control element 31 only needs to have different transmittances for polarized light (TM wave, TE wave) orthogonal to each other, and may have, for example, an anisotropic material, a diffraction grating structure, a meta-surface structure, a photonic crystal structure, or the like.

According to the present embodiment, polarized light having a high transmittance with respect to the polarization control element 31 among the excitation light is oscillated in the solid-state laser medium 3 to prevent the polarized light from becoming a standing wave with the polarization conversion elements 21, 22. As a result, in the solid-state laser medium 3, a standing wave generated by resonance of the excitation light in the first resonator can be inhibited, and the solid-state laser medium 3 can be excited with high efficiency.

Note that, in the embodiment of the present specification, a transparent member HE may be provided at any position between the first reflection layer R1 and the fourth reflection layer R4. In this case, the transparent member HE has a function of a spacer that adjusts the length of the optical resonator 11 or 12 in the optical axis direction. Furthermore, in a case where the transparent member HE is adjacent to the solid-state laser medium 3, the transparent member HE has both a heat exhaust function of discharging the heat of the solid-state laser medium 3 and the function of a spacer. For example, FIG. 2B is a cross-sectional view illustrating a configuration example of the laser element 1 including the transparent member HE. In FIG. 2B, the transparent member HE is adjacent to the solid-state laser medium 3 via the reflection layer R2. The transparent member HE has both a function of adjusting the length of the optical resonator 11 in the optical axis direction and the heat exhaust function.

### Second Embodiment

FIG. 3 is a cross-sectional view illustrating a configuration example of a laser element 1 according to a second embodiment. According to the second embodiment, the polarization conversion element 21 is disposed between the second reflection layer R2 and the solid-state laser medium 3. The polarization conversion element 22 is disposed between the third reflection layer R3 and the polarization control element 32. Furthermore, the polarization control element 32 is provided at any position between the fourth reflection layer R4 and the polarization conversion element 22. More specifically, the polarization control element 32 is provided between the saturable absorber 4 and the polarization conversion element 22. As described above, in the second embodiment, the polarization conversion elements 21, 22 and the polarization control element 32 are provided on the oscillation-light resonator 12 side, and each inhibit the standing wave of the oscillation light of the second wavelength λ2.

The polarization conversion elements 21, 22 each provide a different phase difference to the light in the vibration directions orthogonal to each other in the oscillation light. For example, the polarization conversion elements 21, 22 each provide a phase difference of about one-quarter wavelength (That is, π/2) between the TM wave and the TE wave of the oscillation light. At this time, the principal axes of the polarization conversion elements 21, 22 are perpendicular to each other and inclined at a 45-degree angle relative to a polarization direction defined by the polarization control element 32. Note that the phase difference provided to the oscillation light by the polarization conversion elements 21, 22 is not necessarily one-quarter wavelength. For the polarization conversion elements 21, 22, for example, an anisotropic material, a meta-surface structure, a photonic crystal structure, or the like is used.

As described above, since the polarization conversion elements 21, 22 provide different phase differences to the light in the vibration directions orthogonal to each other in the oscillation light, the oscillation light does not become a standing wave in the solid-state laser medium 3, and efficient laser oscillation is realized. In the second embodiment, the polarization conversion elements 21, 22 act on the oscillation light, but do not act on the excitation light of the first wavelength λ1. However, there is no problem even when the polarization conversion elements 21, 22 act on the excitation light as described later.

The polarization control element 32 as the second polarization control element is provided between the saturable absorber 4 and the polarization conversion element 22, and is disposed on the optical axis of the oscillation-light resonator 12. The polarization control element 32 controls the polarization of the oscillation light of the second wavelength λ2. For the polarization control element 32, for example, a dielectric (e.g., Al₂O₃, SiO₂, Ta₂O₅, and HfO₂), a semiconductor (e.g., GaN, InN, AlN), or the like is used, and a material transparent to the oscillation light is used. Although not illustrated, a grating structure as a fine structure is formed on the surface of the polarization control element 32. As a result, the polarization control element 32 has different transmittances for polarized light (TM wave, TE wave) orthogonal to each other among the oscillation light of the second wavelength λ2. The grating structure may be, for example, an uneven structure having a period equal to or less than the second wavelength λ2 of the oscillation light and having a depth equal to or less than a quarter of the second wavelength λ2 of the oscillation light. The grating structure may be, for example, a one-dimensional surface relief grating structure using 0th-order diffracted light (transmitted light). That is, the pattern of the grating structure may be a so-called line-and-space pattern. As a result, the polarization control element 32 has different transmittances for polarized light (TM wave, TE wave) orthogonal to each other among the 0th-order diffracted light (transmitted light) of the oscillation light. Furthermore, the polarization of the oscillation light is controlled in one direction by the polarization control element 32 instead of the random polarization, so that it is possible to improve the characteristics of the oscillation-light resonator 12, which includes stabilizing the oscillation output and improving wavelength conversion efficiency Note that the polarization control element 32 only needs to have different transmittances for polarized light (TM wave, TE wave) orthogonal to each other, and may have, for example, an anisotropic material, a diffraction grating structure, a meta-surface structure, a photonic crystal structure, or the like.

Other configurations according to the second embodiment may be similar to the corresponding configurations of the first embodiment. Note that the saturable absorber 4 is provided between the polarization control element 32 and the fourth reflection layer R4. However, the saturable absorber 4 may be disposed at any position between the third reflection layer R3 and the fourth reflection layer R4.

According to the second embodiment, polarized light having a high transmittance with respect to the polarization control element 32 among the oscillation light is oscillated in the solid-state laser medium 3 to prevent the polarized light from becoming a standing wave with the polarization conversion elements 21, 22. As a result, in the solid-state laser medium 3, a standing wave generated by the oscillation light resonating in the second resonator is inhibited, and the oscillation light can be output stably and highly efficiently.

### Third Embodiment

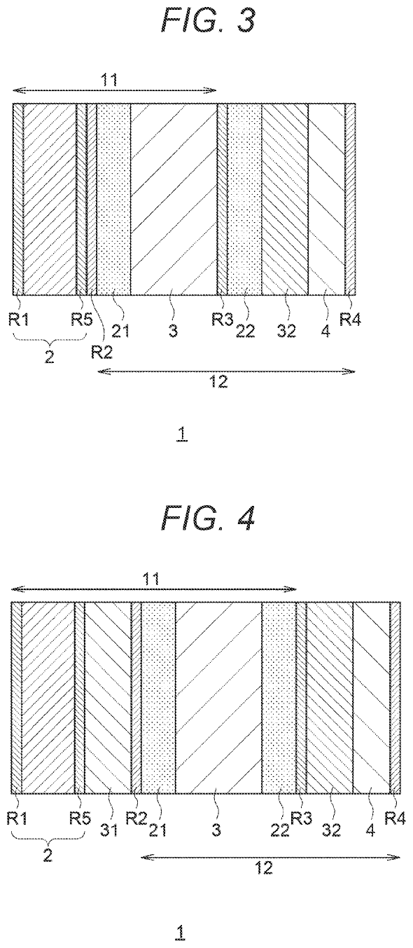

FIG. 4 is a cross-sectional view illustrating a configuration example of a laser element 1 according to a third embodiment. According to the third embodiment, the polarization conversion element 21 is disposed between the second reflection layer R2 and the solid-state laser medium 3. The polarization conversion element 22 is disposed between the solid-state laser medium 3 and the third reflection layer R3. Furthermore, in the third embodiment, both the polarization control elements 31, 32 are provided for the polarization control element. The polarization control element 31 is provided between the fifth reflection layer R5 and the second reflection layer R2. The polarization control element 32 is provided between the saturable absorber 4 and the third reflection layer R3. As described above, in the third embodiment, the polarization conversion elements 21, 22 are shared by both the excitation-light resonator 11 and the oscillation-light resonator 12. Furthermore, the polarization control element 31 is provided on the excitation-light resonator 11 side, and the polarization control element 32 is provided on the oscillation-light resonator 12 side. It is thereby possible to inhibit standing waves of both the excitation light of the first wavelength λ1 and the oscillation light of the second wavelength λ2.

The configurations of the polarization conversion elements 21, 22 may be similar to those of the first and second embodiments. That is, the polarization conversion elements 21, 22 each provide a different phase difference to the light in the vibration directions orthogonal to each other in both the excitation light and the oscillation light. For example, the polarization conversion elements 21, 22 each provide a phase difference of about one-quarter wavelength (that is, π/2) between the TM wave and the TE wave of both the oscillation light and the oscillation light. At this time, the principal axes of the polarization conversion elements 21, 22 are perpendicular to each other and inclined at a 45-degree angle relative to a polarization direction defined by the polarization control element 32. Note that the phase difference provided to the excitation light and the oscillation light by the polarization conversion elements 21, 22 is not necessarily one-quarter wavelength.

As described above, since the polarization conversion elements 21, 22 provide different phase differences to the light in the vibration directions orthogonal to each other in the excitation light and the oscillation light, the excitation light and the oscillation light do not become standing waves in the solid-state laser medium 3, and efficient laser oscillation becomes possible.

The polarization control element 31 is provided between the light emitting element 2 and the second reflection layer R2, and is disposed on the optical axis of the excitation-light resonator 11. The polarization control element 31 controls the polarization of the excitation light of the first wavelength λ1.

The polarization control element 32 is provided between the third reflection layer R3 and the saturable absorber 4, and is disposed on the optical axis of the oscillation-light resonator 12. The polarization control element 32 controls the polarization of the oscillation light of the second wavelength λ2. The configurations of the polarization control elements 31, 32 may be similar to those of the first and second embodiments.

Other configurations of the third embodiment may be similar to the corresponding configurations of the first or second embodiment.

According to the third embodiment, polarized light having a high transmittance with respect to the polarization control element 31 among the excitation light is oscillated in the solid-state laser medium 3 to prevent the polarized light from becoming a standing wave with the polarization conversion elements 21, 22. As a result, the standing wave of the excitation light is inhibited in the solid-state laser medium 3, and the solid-state laser medium 3 can be excited with high efficiency. Furthermore, polarized light having a high transmittance with respect to the polarization control element 32 among the excitation light is oscillated in the solid-state laser medium 3 to prevent the polarized light from becoming a standing wave with the polarization conversion elements 21, 22. As a result, the standing wave of the oscillation light is inhibited in the solid-state laser medium 3, and the laser oscillation can be stabilized and the efficiency can be increased.

### Fourth Embodiment

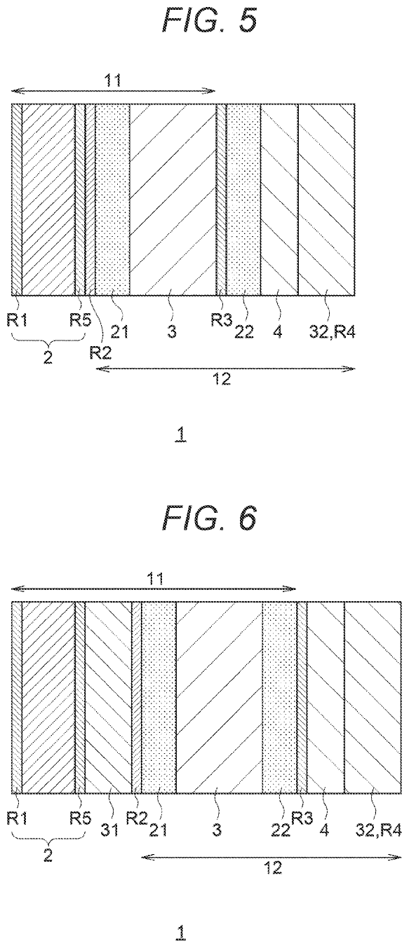

FIG. 5 is a cross-sectional view illustrating a configuration example of a laser element 1 according to a fourth embodiment. In the fourth embodiment, the fourth reflection layer R4 of the second embodiment also has the function of the polarization control element 32. That is, the oscillation light polarization control element 32 and the fourth reflected light R4 are integrally formed. In this case, a fine structure similar to that of the polarization control element 32 is formed on the surface of the fourth reflection layer R4 on the side of the saturable absorber 4. Thereby, the fourth reflection layer R4 can also have the function of the polarization control element 32 with respect to the oscillation light. That is, the fourth reflection layer R4 has different transmittances for polarized light (e.g., TM wave and TE wave) orthogonal to each other among the oscillation light of the second wavelength λ2. As described above, since the polarization control element 32 and the fourth reflected light R4 are not separated but integrated, the laser element 1 according to the fourth embodiment can be further reduced in size.

Other configurations of the fourth embodiment may be similar to corresponding configurations of the second embodiment. Therefore, the fourth embodiment can also obtain the effect of the second embodiment.

### Fifth Embodiment

FIG. 6 is a cross-sectional view illustrating a configuration example of a laser element 1 according to a fifth embodiment. In the fifth embodiment, the fourth reflection layer R4 of the third embodiment also has the function of the polarization control element 32. That is, the oscillation light polarization control element 32 and the fourth reflected light R4 are integrally formed. In this case, a fine structure similar to that of the polarization control element 32 is formed on the surface of the fourth reflection layer R4 on the side of the saturable absorber 4. Thereby, the fourth reflection layer R4 can also have the function of the polarization control element 32 with respect to the oscillation light. That is, the fourth reflection layer R4 has different transmittances for polarized light (e.g., TM wave and TE wave) orthogonal to each other among the oscillation light of the second wavelength λ2. As described above, since the polarization control element 32 and the fourth reflected light R4 are not separated from each other but are integrated with each other, the laser element 1 according to the fifth embodiment can be further reduced in size.

Other configurations of the fifth embodiment may be similar to the corresponding configurations of the third embodiment. Therefore, the fifth embodiment can also obtain the effect of the third embodiment.

### Sixth Embodiment

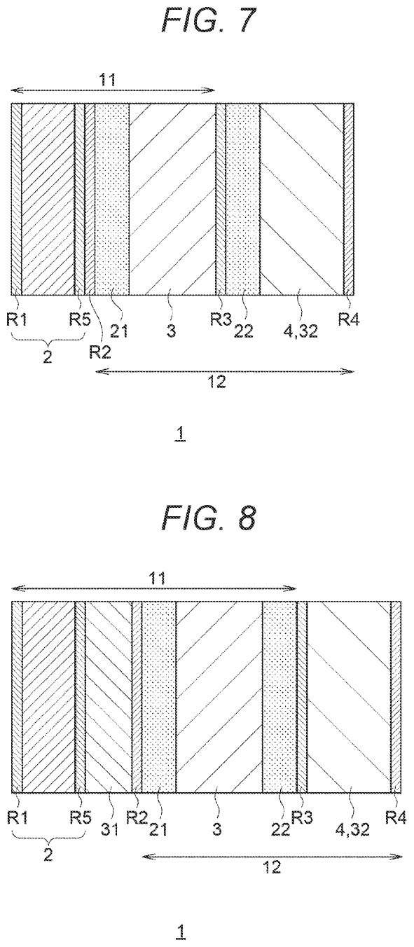

FIG. 7 is a cross-sectional view illustrating a configuration example of a laser element 1 according to a sixth embodiment. In the sixth embodiment, the saturable absorber 4 of the second embodiment also has the function of the polarization control element 32. That is, the oscillation light polarization control element 32 and the saturable absorber 4 are integrally formed. For example, a fine structure similar to that of the polarization control element 32 is formed on the surface of the saturable absorber 4. Thereby, the saturable absorber 4 can also have the function of the polarization control element 32 with respect to the oscillation light. That is, the saturable absorber 4 has different transmittances for polarized light (e.g., TM wave and TE wave) orthogonal to each other among the oscillation light of the second wavelength λ2. Note that the anisotropy of the saturable absorber may be used instead of providing a fine structure. As described above, since the polarization control element 32 and the fourth reflected light R4 are not separated from each other but are integrated with each other, the laser element 1 according to the sixth embodiment can be further reduced in size.

Other configurations of the sixth embodiment may be similar to the corresponding configurations of the second embodiment. Therefore, the sixth embodiment can also obtain the effects of the second embodiment.

### Seventh Embodiment

FIG. 8 is a cross-sectional view illustrating a configuration example of a laser element 1 according to a seventh embodiment. In the seventh embodiment, the saturable absorber 4 of the third embodiment also has the function of the polarization control element 32. That is, the oscillation light polarization control element 32 and the saturable absorber 4 are integrally formed. For example, a fine structure similar to that of the polarization control element 32 is formed on the surface of the saturable absorber 4. Thereby, the saturable absorber 4 can also have the function of the polarization control element 32 with respect to the oscillation light. That is, the saturable absorber 4 has different transmittances for polarized light (e.g., TM wave and TE wave) orthogonal to each other among the oscillation light of the second wavelength λ2. Note that the anisotropy of the saturable absorber may be used instead of providing a fine structure. As described above, since the polarization control element 32 and the saturable absorber 4 are not separated from each other but are integrated with each other, the laser element 1 according to the seventh embodiment can be further reduced in size.

Other configurations of the seventh embodiment may be similar to the corresponding configurations of the third embodiment. Therefore, the seventh embodiment can also obtain the effect of the third embodiment.

### Eighth Embodiment

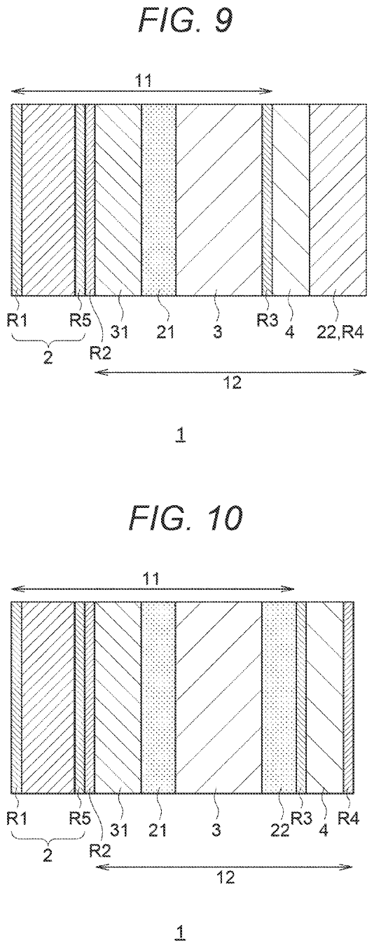

FIG. 9 is a cross-sectional view illustrating a configuration example of a laser element 1 according to an eighth embodiment. In the eighth embodiment, the fourth reflection layer R4 of the second embodiment also has the function of the polarization conversion element 22. That is, the polarization conversion element 22 and the fourth reflection layer R4 are integrally formed. In this case, similarly to the polarization conversion element 22, the saturable absorber 4 is formed by, for example, an anisotropic material, a meta-surface structure, a photonic crystal structure, or the like. Thereby, the fourth reflection layer R4 can provide a different phase difference to the light in the vibration directions orthogonal to each other in the oscillation light. As described above, since the polarization conversion element 22 and the fourth reflected light R4 are not separated from each other but are integrated with each other, the laser element 1 according to the eighth embodiment can be further reduced in size.

Note that, in the eighth embodiment, the polarization control element 31 is provided between the second reflection layer R2 and the polarization conversion element 21. That is, the polarization control element 31 is provided on the side opposite to the fourth reflection layer R4 having a polarization conversion function with the solid-state laser medium 3 interposed therebetween. The polarization control element 31 has different transmittances for polarized light orthogonal to each other in the oscillation light.

Other configurations of the eighth embodiment may be similar to the corresponding configurations of the second embodiment. Therefore, the eighth embodiment can also obtain the effect of the second embodiment.

### Ninth Embodiment

FIG. 10 is a cross-sectional view illustrating a configuration example of a laser element 1 according to a ninth embodiment. In the ninth embodiment, the polarization control element 31 of the third embodiment also has the function of the polarization control element 32. That is, the polarization control element 32 of the oscillation light is omitted, and the polarization control element 31 controls the polarization of both the oscillation light and the excitation light. The polarization control element 31 is provided between the second reflected light R2 and the polarization conversion element 21, and is shared by the excitation-light resonator 11 and the oscillation-light resonator 12. For example, a fine structure that realizes the functions of both the polarization control elements 31, 32 of the third embodiment is formed on the surface of the polarization control element 31. Thus, the polarization control element 31 can control polarization of both the excitation light and the oscillation light. That is, the polarization control element 31 has a fine structure on the surface so as to have different transmittances for polarized light orthogonal to each other in the excitation light and have different transmittances for polarized light orthogonal to each other in the oscillation light. Since the polarization control element 31 also has the function of the polarization control element 32, the laser element 1 according to the ninth embodiment can be further reduced in size.

Other configurations of the ninth embodiment may be similar to the corresponding configurations of the third embodiment. Therefore, the ninth embodiment can also obtain the effect of the third embodiment.

### Tenth Embodiment

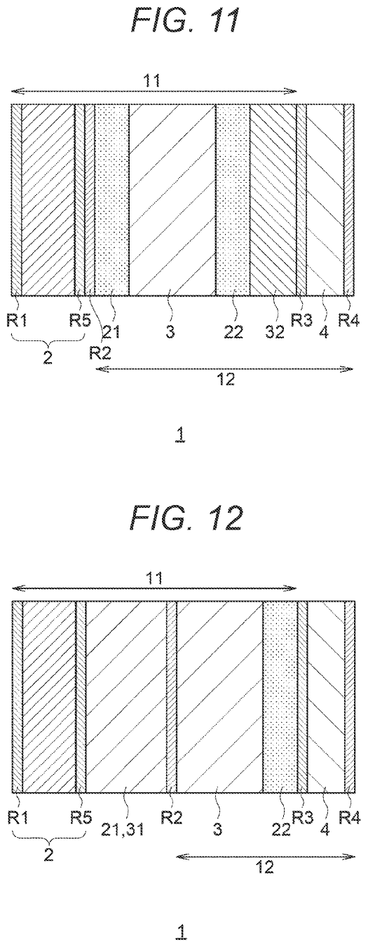

FIG. 11 is a cross-sectional view illustrating a configuration example of a laser element 1 according to a tenth embodiment. In the tenth embodiment, the polarization control element 32 of the third embodiment also has the function of the polarization control element 31. That is, the polarization control element 31 of the excitation light is omitted, and the polarization control element 32 controls the polarization of both the oscillation light and the excitation light. The polarization control element 32 is provided between the polarization conversion element 22 and the third reflected light R3, and is shared by the excitation-light resonator 11 and the oscillation-light resonator 12. For example, a fine structure that realizes the functions of both the polarization control elements 31, 32 of the third embodiment is formed on the surface of the polarization control element 32. Thus, the polarization control element 32 can control polarization of both the excitation light and the oscillation light. That is, the polarization control element 32 has a fine structure on the surface so as to have different transmittances for polarized light orthogonal to each other in the excitation light and have different transmittances for polarized light orthogonal to each other in the oscillation light. Since the polarization control element 32 also has the function of the polarization control element 31, the laser element 1 according to the tenth embodiment can be further reduced in size.

Other configurations of the tenth embodiment may be similar to the corresponding configurations of the third embodiment. Therefore, the effect of the third embodiment can also be obtained in the tenth embodiment.

### Eleventh Embodiment

FIG. 12 is a cross-sectional view illustrating a configuration example of a laser element 1 according to an eleventh embodiment. In the eleventh embodiment, the polarization conversion element 21 of the first embodiment also has the function of the polarization control element 31. That is, the polarization control element 31 of the excitation light is omitted, and the polarization conversion element 21 also has a function of controlling the polarization of the excitation light. The polarization conversion element 21 is disposed between the light emitting element 2 and the second reflected light R2, and is provided in the excitation-light resonator 11. Thus, the polarization conversion element 21 can control the polarization of the excitation light. That is, the polarization conversion element 21 has different transmittances for polarized light (TM wave, TE wave) orthogonal to each other among the excitation light. As described above, since the polarization conversion element 21 also has the function of the polarization control element 31, the laser element 1 according to the eleventh embodiment can be further reduced in size.

Other configurations of the eleventh embodiment may be similar to the corresponding configurations of the first embodiment. Therefore, the eleventh embodiment can also obtain the effect of the first embodiment.

### Twelfth Embodiment

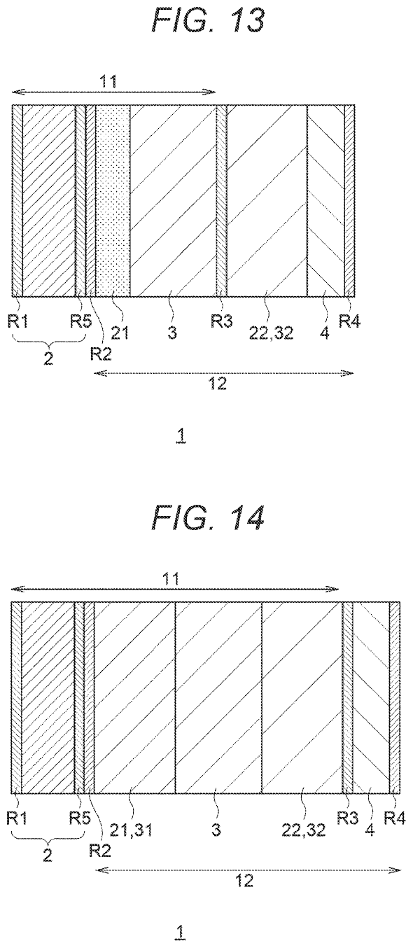

FIG. 13 is a cross-sectional view illustrating a configuration example of a laser element 1 according to a twelfth embodiment. In the twelfth embodiment, the polarization conversion element 22 of the second embodiment also has the function of the polarization control element 32. That is, the polarization control element 32 of the oscillation light is omitted, and the polarization conversion element 22 also has a function of controlling the polarization of the oscillation light. The polarization conversion element 22 is disposed between the saturable absorber 4 and the third reflected light R3, and is provided in the oscillation-light resonator 12. Thus, the polarization conversion element 22 can control the polarization of the oscillation light. That is, the polarization conversion element 22 has different transmittances for polarized light (TM wave, TE wave) orthogonal to each other among the oscillation light. As described above, since the polarization conversion element 22 also has the function of the polarization control element 32, the laser element 1 according to the twelfth embodiment can be further reduced in size.

Other configurations of the twelfth embodiment may be similar to the corresponding configurations of the second embodiment. Therefore, the twelfth embodiment can also obtain the effect of the second embodiment.

### Thirteenth Embodiment

FIG. 14 is a cross-sectional view illustrating a configuration example of a laser element 1 according to a thirteenth embodiment. In the thirteenth embodiment, the polarization conversion element 21 of the third embodiment has the function of the polarization control element 31, and the polarization conversion element 22 has the function of the polarization control element 32. That is, the polarization control element 31 for the excitation light and the polarization control element 32 for the oscillation light are omitted. The polarization conversion element 21 also has a function of controlling the polarization of the excitation light, and the polarization conversion element 22 also has a function of controlling the polarization of the oscillation light.

The polarization conversion element 21 is disposed between the second reflected light R2 and the solid-state laser medium 3, and is shared by the excitation-light resonator 11 and the oscillation-light resonator 12. Thus, the polarization conversion element 21 can control the polarization of the excitation light.

The polarization conversion element 22 is disposed between the solid-state laser medium 3 and the third reflected light R3, and is shared by the excitation-light resonator 11 and the oscillation-light resonator 12. Thus, the polarization conversion element 22 can control the polarization of the oscillation light.

Since the polarization conversion elements 21, 22 also have the functions of the polarization control elements 31, 32, respectively, the laser element 1 according to the thirteenth embodiment can be further reduced in size.

Other configurations of the thirteenth embodiment may be similar to the corresponding configurations of the third embodiment. Therefore, the effect of the third embodiment can also be obtained in the thirteenth embodiment.

### [Endoscope System]

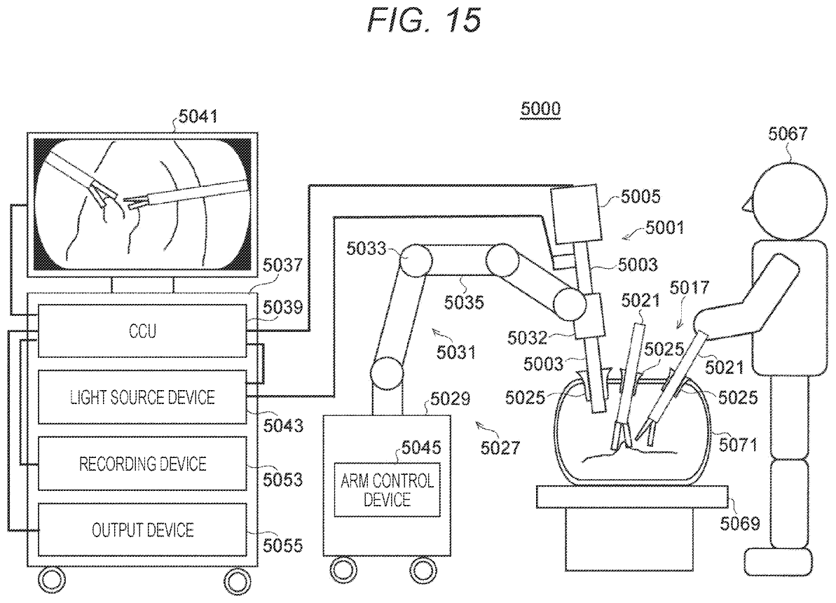

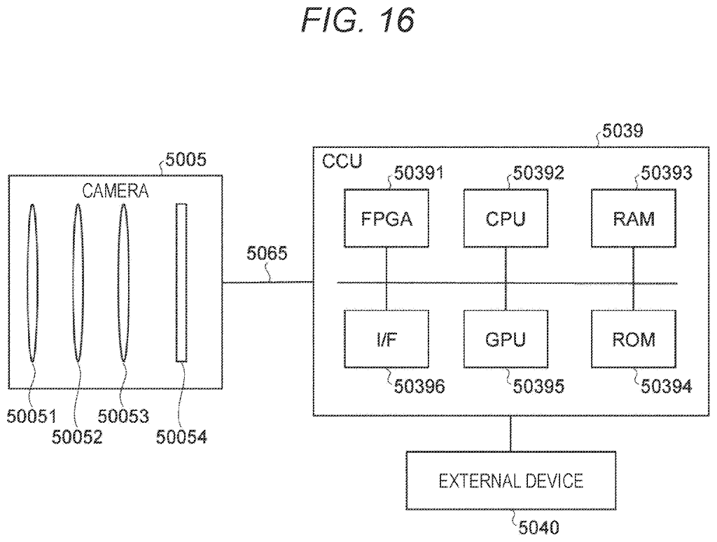

An example of an endoscope system will be described with reference to FIGS. 15 and 16. FIG. 15 is a diagram illustrating an example of a schematic configuration of an endoscope system 5000 to which the technology according to the present disclosure can be applied. FIG. 16 is a diagram illustrating an example of a configuration of the endoscope 5001 and a camera control unit (CCU) 5039. FIG. 15 illustrates a state in which an operator (e.g., doctor) 5067, who is a surgery participant, is performing surgery on a patient 5071 on a patient bed 5069 using the endoscope system 5000. As illustrated in FIG. 15, the endoscope system 5000 includes the endoscope 5001 that is a medical imaging device, the CCU 5039, a light source device 5043, a recording device 5053, an output device 5055, and a support device 5027 that supports the endoscope 5001.

In endoscopic surgery, insertion assisting tools called trocars 5025 are punctured into the patient 5071. Then, a scope 5003 connected to the endoscope 5001 and surgical tools 5021 are inserted into a body of the patient 5071 through the trocars 5025. The surgical tools 5021 include: an energy device such as an electric scalpel; and forceps, for example.

A surgical image that is a medical image in which the inside of the body of the patient 5071 is captured by the endoscope 5001 is displayed on a display device 5041. The operator 5067 performs a procedure on a surgical target using the surgical tools 5021 while viewing the surgical image displayed on the display device 5041. The medical image is not limited to the surgical image, and may be a diagnostic image captured during diagnosis.

### [Endoscope]

The endoscope 5001 is an imaging unit for capturing the inside of the body of the patient 5071, and is, for example, as illustrated in FIG. 16, a camera 5005 including a condensing optical system 50051 for condensing incident light, a zooming optical system 50052 capable of optical zooming by changing a focal length of the imaging unit, a focusing optical system 50053 capable of focus adjustment by changing the focal length of the imaging unit, and a light receiving sensor 50054. The endoscope 5001 condenses the light through the connected scope 5003 on the light receiving sensor 50054 to generate a pixel signal, and outputs the pixel signal through a transmission system to the CCU 5039. The scope 5003 is an insertion part that includes an objective lens at a distal end and guides the light from the connected light source device 5043 into the body of the patient 5071. The scope 5003 is, for example, a rigid scope for a rigid endoscope and a flexible scope for a flexible endoscope. The scope 5003 may be a direct viewing scope or an oblique viewing scope. The pixel signal only needs to be a signal based on a signal output from a pixel, and is, for example, a raw signal or an image signal. The transmission system connecting the endoscope 5001 to the CCU 5039 may include a memory, and the memory may store parameters related to the endoscope 5001 and the CCU 5039. The memory may be disposed at a connection portion of the transmission system or on a cable. For example, the memory of the transmission system may store the parameters before shipment of the endoscope 5001 or the parameters changed when current is applied, and an operation of the endoscope may be changed based on the parameters read from the memory. A set of the camera and the transmission system may be referred to as an endoscope. The light receiving sensor 50054 is a sensor for converting the received light into the pixel signal, and is, for example, a complementary metal-oxide-semiconductor (CMOS) imaging sensor. The light receiving sensor 50054 is preferably an imaging sensor having a Bayer array capable of color imaging. The light receiving sensor 50054 is also preferably an imaging sensor having a number of pixels corresponding to a resolution of, for example, 4K (3840 horizontal pixels×2160 vertical pixels), 8K (7680 horizontal pixels×4320 vertical pixels), or square 4K (3840 or more horizontal pixels×3840 or more vertical pixels). The light receiving sensor 50054 may be one sensor chip, or a plurality of sensor chips. For example, a prism may be provided to separate the incident light into predetermined wavelength bands, and the wavelength bands may be imaged by different light receiving sensors. A plurality of light receiving sensors may be provided for stereoscopic viewing. The light receiving sensor 50054 may be a sensor having a chip structure including an arithmetic processing circuit for image processing, or may be a sensor for time of flight (ToF). The transmission system is, for example, an optical fiber cable system or a wireless transmission system. The wireless transmission only needs to be capable of transmitting the pixel signal generated by the endoscope 5001, and, for example, the endoscope 5001 may be wirelessly connected to the CCU 5039, or the endoscope 5001 may be connected to the CCU 5039 via a base station in an operating room. At this time, the endoscope 5001 may transmit not only the pixel signal, but also simultaneously information (for example, a processing priority of the pixel signal and/or a synchronization signal) related to the pixel signal. In the endoscope, the scope may be integrated with the camera, and the light receiving sensor may be provided at the distal end of the scope.

### [CCU (Camera Control Unit)]

The CCU 5039 is a control device that integrally controls the connected endoscope 5001 and light source device 5043, and is, for example, an information processing device including an FPGA 50391, a CPU 50392, a RAM 50393, a ROM 50394, a GPU 50395, and an I/F 50396 as illustrated in FIG. 16. The CCU 5039 may control the display device 5041, the recording device 5053, and the output device 5055 connected to the CCU 5039 in an integrated manner. The CCU 5039 controls, for example, irradiation timing, irradiation intensity, and a type of an irradiation light source of the light source device 5043. The CCU 5039 also performs image processing, such as development processing (for example, demosaic processing) and correction processing, on the pixel signal output from the endoscope 5001, and outputs the processed image signal (for example, an image) to an external device such as the display device 5041. The CCU 5039 also transmits a control signal to the endoscope 5001 to control driving of the endoscope 5001. The control signal is information on an imaging condition such as a magnification or the focal length of the imaging section. The CCU 5039 may have a function to down-convert the image, and may be configured to be capable of simultaneously outputting a higher-resolution (for example, 4K) image to the display device 5041 and a lower-resolution (for example, high-definition (HD)) image to the recording device 5053.

The CCU 5039 may be connected to external equipment (such as a recording device, a display device, an output device, and a support device) via an IP converter for converting the signal into a predetermined communication protocol (such as the Internet Protocol (IP)). The connection between the IP converter and the external equipment may be established using a wired network, or a part or the whole of the network may be established using a wireless network. For example, the IP converter on the CCU 5039 side may have a wireless communication function, and may transmit the received image to an IP switcher or an output side IP converter via a wireless communication network, such as the fifth-generation mobile communication system (5G) or the sixth-generation mobile communication system (6G).

### [Light Source Device]

The light source device 5043 is a device capable of emitting the light having predetermined wavelength bands, and includes, for example, a plurality of light sources and a light source optical system for guiding the light of the light sources. The light sources are, for example, xenon lamps, light-emitting diode (LED) light sources, or laser diode (LD) light sources. The light source device 5043 includes, for example, the LED light sources corresponding to three respective primary colors of red (R), green (G), and blue (B), and controls output intensity and output timing of each of the light sources to emit white light. The light source device 5043 may include a light source capable of emitting special light used for special light observation, in addition to the light sources for emitting normal light for normal light observation. The special light is light having a predetermined wavelength band different from that of the normal light being light for the normal light observation, and is, for example, near-infrared light (light having a wavelength of 760 nm or longer), infrared light, blue light, or ultraviolet light. The normal light is, for example, the white light or green light. In narrow band imaging that is a kind of special light observation, blue light and green light are alternately emitted, and thus the narrow band imaging can image a predetermined tissue such as a blood vessel in a mucosal surface at high contrast using wavelength dependence of light absorption in the tissue of the body. In fluorescence observation that is a kind of special light observation, excitation light is emitted for exciting an agent injected into the tissue of the body, and fluorescence emitted by the tissue of the body or the agent as a label is received to obtain a fluorescent image, and thus the fluorescence observation can facilitate the operator to view, for example, the tissue of the body that is difficult to be viewed by the operator with the normal light. For example, in fluorescence observation using the infrared light, the infrared light having an excitation wavelength band is emitted to an agent, such as indocyanine green (ICG), injected into the tissue of the body, and the fluorescence light from the agent is received, whereby the fluorescence observation can facilitate viewing of a structure and an affected part of the tissue of the body. In the fluorescence observation, an agent (such as 5-aminolevulinic acid (5-ALA)) may be used that emits fluorescence in a red wavelength band by being excited by the special light in a blue wavelength band. The type of the irradiation light of the light source device 5043 is set by control of the CCU 5039. The CCU 5039 may have a mode of controlling the light source device 5043 and the endoscope 5001 to alternately perform the normal light observation and the special light observation. At this time, information based on a pixel signal obtained by the special light observation is preferably superimposed on a pixel signal obtained by the normal light observation. The special light observation may be an infrared light observation to observe a site inside the surface of an organ and a multi-spectrum observation utilizing hyperspectral spectroscopy. A photodynamic therapy may be incorporated.

### [Recording Device]

The recording device 5053 is a device for recording the pixel signal (for example, an image) acquired from the CCU 5039, and is, for example, a recorder. The recording device 5053 records an image acquired from the CCU 5039 in a hard disk drive (HDD), a Super Density Disc (SDD), and/or an optical disc. The recording device 5053 may be connected to a network in a hospital to be accessible from equipment outside the operating room. The recording device 5053 may have a down-convert function or an up-convert function.

### [Display Device]

The display device 5041 is a device capable of displaying the image, and is, for example, a display monitor. The display device 5041 displays a display image based on the pixel signal acquired from the CCU 5039. The display device 5041 may include a camera and a microphone to function as an input device that allows instruction input through gaze recognition, voice recognition, and gesture.

### [Output Device]

The output device 5055 is a device for outputting the information acquired from the CCU 5039, and is, for example, a printer. The output device 5055 prints, for example, a print image based on the pixel signal acquired from the CCU 5039 on a sheet of paper.

### [Support Device]

The support device 5027 is an articulated arm including a base 5029 including an arm control device 5045, an arm 5031 extending from the base 5029, and a holding part 5032 mounted at a distal end of the arm 5031. The arm control device 5045 includes a processor such as a CPU, and operates according to a predetermined computer program to control driving of the arm 5031. The support device 5027 uses the arm control device 5045 to control parameters including, for example, lengths of links 5035 constituting the arm 5031 and rotation angles and torque of joints 5033 so as to control, for example, the position and attitude of the endoscope 5001 held by the holding part 5032. This control can change the position or attitude of the endoscope 5001 to a desired position or attitude, makes it possible to insert the scope 5003 into the patient 5071, and can change the observed area in the body. The support device 5027 functions as an endoscope support arm for supporting the endoscope 5001 during the operation. Thus, the support device 5027 can play a role of a scopist who is an assistant holding the endoscope 5001. The support device 5027 may be a device for holding a microscope device 5301 to be described later, and can be called a medical support arm. The support device 5027 may be controlled using an autonomous control method by the arm control device 5045, or may be controlled using a control method in which the arm control device 5045 performs the control based on input of a user. The control method may be, for example, a master-slave method in which the support device 5027 serving as a slave device (replica device) that is a patient cart is controlled based on a movement of a master device (primary device) that is an operator console at a hand of the user. The support device 5027 may be remotely controllable from outside the operating room.

The example of the endoscope system 5000 to which the technology according to the present disclosure is applicable has been described above. For example, the technology according to the present disclosure may be applied to a microscope system.

### [Microscope System]

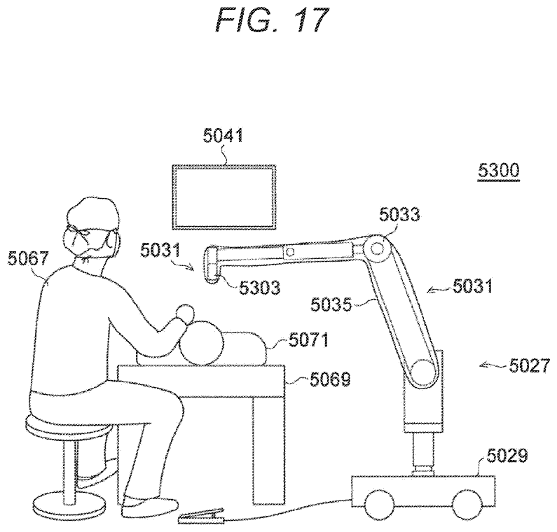

FIG. 17 is a diagram illustrating an example of a schematic configuration of a microscopic surgery system to which the technology according to the present disclosure is applicable. In the following description, the same components as those of the endoscope system 5000 will be denoted by the same reference numerals, and the description thereof will not be repeated.

FIG. 17 schematically illustrates a state in which the operator 5067 is performing surgery on the patient 5071 on the patient bed 5069 using a microscopic surgery system 5300. Note that, for the sake of simplicity, FIG. 17 does not illustrate a cart 5037 among the components of the microscopic surgery system 5300, and illustrates the microscope device 5301 instead of the endoscope 5001 in a simplified manner. The microscope device 5301 may refer to a microscope 5303 provided at the distal end of the links 5035, or may refer to the overall configuration including the microscope 5303 and the support device 5027.

As illustrated in FIG. 17, during the operation, the microscopic surgery system 5300 is used to display an image of a surgical site captured by the microscope device 5301 in a magnified manner on the display device 5041 installed in the operating room. The display device 5041 is installed in a position facing the operator 5067, and the operator 5067 performs various procedures, such as excision of an affected part, on the surgical site while observing the state of the surgical site using the image displayed on the display device 5041. The microscopic surgery system is used in, for example, ophthalmic operation and neurosurgical operation.

The respective examples of the endoscope system 5000 and the microscopic surgery system 5300 to which the technology according to the present disclosure is applicable have been described above. Systems to which the technology according to the present disclosure is applicable are not limited to such examples. For example, the support device 5027 can support, at the distal end thereof, another observation device or another surgical tool instead of the endoscope 5001 or the microscope 5303. Examples of the other applicable observation device include forceps, tweezers, a pneumoperitoneum tube for pneumoperitoneum, and an energy treatment tool for incising a tissue or sealing a blood vessel by cauterization. By using the support device to support the observation device or the surgical tool described above, the position thereof can be more stably fixed and the load of the medical staff can be lower than in a case where the medical staff manually supports the observation device or the surgical tool. The technology according to the present disclosure may be applied to a support device for supporting such a component other than the microscope.

The technology according to the present disclosure is suitably applicable to the surgical tools 5021 among the components described above. Specifically, by irradiating the affected site of the patient with a short-pulse laser pulse from the laser element 1 according to the present embodiment, it is possible to more safely and reliably treat the affected site without damaging the periphery of the affected site.

Note that the present technology can have the following configurations.

(1)

A laser element including:
a laminated semiconductor layer including a first reflection layer with respect to a first wavelength and an active layer that performs surface emission at the first wavelength;
a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface opposite to the first surface;
a fourth reflection layer with respect to the second wavelength, the forth reflection layer being disposed on the second surface or disposed on a rear side of the optical axis with respect to the second surface;
a first resonator that causes light of the first wavelength to resonate between the first reflection layer and the third reflection layer;
a second resonator that causes light of the second wavelength to resonate between the second reflection layer and the fourth reflection layer;
a first polarization conversion element that is provided between the first reflection layer and the laser medium, and causes a phase difference for light in vibration directions orthogonal to each other in the light of the first wavelength or the light of the second wavelength;
a second polarization conversion element that is provided between the second reflection layer and the laser medium, and causes a phase difference for light in vibration directions orthogonal to each other in the light of the first wavelength or the light of the second wavelength; and
at least one of a first polarization control element or a second polarization control element that is provided between the first reflection layer and the fourth reflection layer, and controls polarization of the light of the first wavelength or the light of the second wavelength,
in which the optical axis of the laminated semiconductor layer, an optical axis of the laser medium, and optical axes of the first polarization conversion element, the second polarization conversion element, and the first polarization control element or the second polarization control element are coaxially arranged.
   (2)

The laser element according (1), in which an anisotropic material, a meta-surface structure, or a photonic crystal structure is used for the first polarization conversion element and the second polarization conversion element.

(3)

The laser element according (1) or (2), in which each of the first polarization conversion element and the second polarization conversion element provides a phase difference of about one-quarter wavelength for light in vibration directions orthogonal to each other in the light of the first or second wavelength.

(4)

The laser element according to any one of (1) to (3), further including a fifth reflection layer provided on the laser medium side of the laminated semiconductor layer.

(5)

The laser element according to any one of (1) to (4), in which the first polarization control element is provided between the first reflection layer and the first polarization conversion element, and controls polarization of the light of the first wavelength.

(6)

The laser element according to any one of (1) to (5), in which the second polarization control element is provided between the fourth reflection layer and the second polarization conversion element and controls polarization of the light of the second wavelength.

(7)

The laser element according to any one of (1) to (6), in which the first polarization control element has a fine structure on a surface so as to have different transmittances for polarized light orthogonal to each other among the light of the first wavelength.

(8)

The laser element according to any one of (1) to (7), in which the second polarization control element has a fine structure on a surface so as to have different transmittances for polarized light orthogonal to each other among the light of the second wavelength.

(9)

The laser element according to any one of (1) to (8), further including a saturable absorber provided between the third reflection layer and the fourth reflection layer.

(10)

The laser element according to any one of (1) to (9), in which the first polarization conversion element is disposed between the first polarization control element and the second reflection layer, and the second polarization conversion element is disposed between the laser medium and the third reflection layer.

(11)

The laser element according to any one of (1) to (10), in which the first polarization conversion element is disposed between the second reflection layer and the laser medium, and the second polarization conversion element is disposed between the third reflection layer and the second polarization control element.

(12)

The laser element according to any one of (1) to (11), in which the first polarization conversion element is disposed between the second reflection layer and the laser medium, and the second polarization conversion element is disposed between the laser medium and the third reflection layer.

(13)

The laser element according to any one of (1) to (12), in which the fourth reflection layer has a fine structure on a surface so as to have different transmittances for polarized light orthogonal to each other among the light of the second wavelength.

(14) The laser element according to (9), in which the saturable absorber has a fine structure on a surface so as to have different transmittances for polarized light orthogonal to each other among the light of the second wavelength.
(15)

The laser element according to any one of (1) to (14), in which the fourth reflection layer causes a phase difference for light in vibration directions orthogonal to each other in the light of the second wavelength.

(16)

The laser element according to any one of (1) to (15), in which the first polarization control element is provided between the second reflection layer and the first polarization conversion element, and the first polarization control element has a fine structure on a surface so as to have different transmittances for polarized light orthogonal to each other among the light of the first wavelength and have different transmittances for polarized light orthogonal to each other among the light of the second wavelength.

(17)

The laser element according to any one of (1) to (16), in which
the second polarization control element is provided between the third reflection layer and the second polarization conversion element, and
the first polarization control element has a fine structure on a surface so as to have different transmittances for polarized light orthogonal to each other among the light of the first wavelength and have different transmittances for polarized light orthogonal to each other among the light of the second wavelength.
   (18)

The laser element according to any one of (1) to (17), in which the first polarization conversion element has a fine structure on a surface so as to have different transmittances for polarized light orthogonal to each other among the light of the first wavelength.

(19)

The laser element according to any one of (1) to (18), in which the second polarization conversion element has a fine structure on a surface so as to have different transmittances for polarized light orthogonal to each other among the light of the second wavelength.

(20)

The laser element according to any one of (1) to (19), in which the laminated semiconductor layer, the laser medium, the fourth reflection layer, the first resonator, the second resonator, the first polarization conversion element, the second polarization conversion element, and the first polarization control element or the second polarization control element are integrally bonded.

(21)

The laser element according to any one of (1) to (20), further including a transparent member provided at any position between the first reflection layer and the fourth reflection layer.

(22)

An electronic device including:
a laser element; and
a control unit that performs control to emit light from the laser element,
in which
the laser element includes
a laminated semiconductor layer including a first reflection layer with respect to a first wavelength and an active layer that performs surface emission at the first wavelength,
a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface on a side opposite to the first surface,
a fourth reflection layer with respect to the second wavelength, the forth reflection layer being disposed on the second surface or disposed on a rear side of the optical axis with respect to the second surface,
a first resonator that causes light of the first wavelength to resonate between the first reflection layer and the third reflection layer,
a second resonator that causes light of the second wavelength to resonate between the second reflection layer and the fourth reflection layer,
a first polarization conversion element that is provided between the first reflection layer and the laser medium, and causes a phase difference for light in vibration directions orthogonal to each other in the light of the first wavelength,
a second polarization conversion element that is provided between the second reflection layer and the laser medium, and causes a phase difference for light in vibration directions orthogonal to each other in the light of the second wavelength, and
at least one of a first polarization control element or a second polarization control element that is provided between the first reflection layer and the fourth reflection layer, and controls polarization of the light of the first wavelength or the light of the second wavelength, and
the optical axis of the laminated semiconductor layer, an optical axis of the laser medium, and optical axes of the first polarization conversion element, the second polarization conversion element, and the first polarization control element or the second polarization control element are coaxially arranged.

Note that the present disclosure is not limited to the embodiments described above, and various modifications can be made without departing from the gist of the present disclosure. Furthermore, the effects described in the present specification are merely examples and are not limited, and other effects may be provided.

### REFERENCE SIGNS LIST

2 Light emission element
5 Substrate
R5 Fifth reflection layer
6 Cladding layer
7 Active layer
8 Cladding layer
11 Excitation-light resonator
12 Oscillation-light resonator
R1 First reflection layer
R2 Second reflection layer
R3 Third reflection layer
R4 Fourth reflection layer
1 Laser element
21, 22 Polarization conversion element
31 Polarization control element
4 Saturable absorber

1. A laser element comprising:
a laminated semiconductor layer including a first reflection layer with respect to a first wavelength and an active layer that performs surface emission at the first wavelength;
a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface opposite to the first surface;
a fourth reflection layer with respect to the second wavelength, the forth reflection layer being disposed on the second surface or disposed on a rear side of the optical axis with respect to the second surface;
a first resonator that causes light of the first wavelength to resonate between the first reflection layer and the third reflection layer;
a second resonator that causes light of the second wavelength to resonate between the second reflection layer and the fourth reflection layer;
a first polarization conversion element that is provided between the first reflection layer and the laser medium, and causes a phase difference for light in vibration directions orthogonal to each other in the light of the first wavelength or the light of the second wavelength;
a second polarization conversion element that is provided between the fourth reflection layer and the laser medium, and causes a phase difference for light in vibration directions orthogonal to each other in the light of the first wavelength or the light of the second wavelength; and
at least one of a first polarization control element or a second polarization control element that is provided between the first reflection layer and the fourth reflection layer, and controls polarization of the light of the first wavelength or the light of the second wavelength,
wherein the optical axis of the laminated semiconductor layer, an optical axis of the laser medium, and optical axes of the first polarization conversion element, the second polarization conversion element, and the first polarization control element or the second polarization control element are coaxially arranged.

2. The laser element according to claim 1, wherein an anisotropic material, a meta-surface structure, or a photonic crystal structure is used for the first polarization conversion element and the second polarization conversion element.

3. The laser element according to claim 1, wherein each of the first polarization conversion element and the second polarization conversion element provides a phase difference of about one-quarter wavelength for light in vibration directions orthogonal to each other in the light of the first or second wavelength.

4. The laser element according to claim 1, further comprising a fifth reflection layer provided on the laser medium side of the laminated semiconductor layer.

5. The laser element according to claim 1, wherein the first polarization control element is provided between the first reflection layer and the first polarization conversion element, and controls polarization of the light of the first wavelength.

6. The laser element according to claim 1, wherein the second polarization control element is provided between the fourth reflection layer and the second polarization conversion element and controls polarization of the light of the second wavelength.

7. The laser element according to claim 1, wherein the first polarization control element has a fine structure on a surface so as to have different transmittances for polarized light orthogonal to each other among the light of the first wavelength.

8. The laser element according to claim 1, wherein the second polarization control element has a fine structure on a surface so as to have different transmittances for polarized light orthogonal to each other among the light of the second wavelength.

9. The laser element according to claim 1, further comprising a saturable absorber provided between the third reflection layer and the fourth reflection layer.

10. The laser element according to claim 1, wherein
the first polarization conversion element is disposed between the first polarization control element and the second reflection layer, and
the second polarization conversion element is disposed between the laser medium and the third reflection layer.

11. The laser element according to claim 1, wherein the first polarization conversion element is disposed between the second reflection layer and the laser medium, and the second polarization conversion element is disposed between the third reflection layer and the second polarization control element.

12. The laser element according to claim 1, wherein the first polarization conversion element is disposed between the second reflection layer and the laser medium, and the second polarization conversion element is disposed between the laser medium and the third reflection layer.

13. The laser element according to claim 1, wherein the fourth reflection layer has a fine structure on a surface so as to have different transmittances for polarized light orthogonal to each other among the light of the second wavelength.

14. The laser element according to claim 9, wherein the saturable absorber has a fine structure on a surface so as to have different transmittances for polarized light orthogonal to each other among the light of the second wavelength.

15. The laser element according to claim 1, wherein the fourth reflection layer causes a phase difference for light in vibration directions orthogonal to each other in the light of the second wavelength.

16. The laser element according to claim 1, wherein
the first polarization control element is provided between the second reflection layer and the first polarization conversion element, and
the first polarization control element has a fine structure on a surface so as to have different transmittances for polarized light orthogonal to each other among the light of the first wavelength and have different transmittances for polarized light orthogonal to each other among the light of the second wavelength.

17. The laser element according to claim 1, wherein
the second polarization control element is provided between the third reflection layer and the second polarization conversion element, and
the second polarization control element has a fine structure on a surface so as to have different transmittances for polarized light orthogonal to each other among the light of the first wavelength and have different transmittances for polarized light orthogonal to each other among the light of the second wavelength.

18. The laser element according to claim 1, wherein the first polarization conversion element has a fine structure on a surface so as to have different transmittances for polarized light orthogonal to each other among the light of the first wavelength.

19. The laser element according to claim 1, wherein the second polarization conversion element has a fine structure on a surface so as to have different transmittances for polarized light orthogonal to each other among the light of the second wavelength.

20. The laser element according to claim 1, wherein the laminated semiconductor layer, the laser medium, the fourth reflection layer, the first resonator, the second resonator, the first polarization conversion element, the second polarization conversion element, and the first polarization control element or the second polarization control element are integrally bonded.

21. The laser element according to claim 1, further comprising a transparent member provided at any position between the first reflection layer and the fourth reflection layer.

22. An electronic device comprising:
a laser element; and
a control unit that performs control to emit light from the laser element,
wherein
the laser element includes
a laminated semiconductor layer including a first reflection layer with respect to a first wavelength and an active layer that performs surface emission at the first wavelength,
a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface on a side opposite to the first surface,
a fourth reflection layer with respect to the second wavelength, the forth reflection layer being disposed on the second surface or disposed on a rear side of the optical axis with respect to the second surface,
a first resonator that causes light of the first wavelength to resonate between the first reflection layer and the third reflection layer,
a second resonator that causes light of the second wavelength to resonate between the second reflection layer and the fourth reflection layer,
a first polarization conversion element that is provided between the first reflection layer and the laser medium, and causes a phase difference for light in vibration directions orthogonal to each other in the light of the first wavelength,
a second polarization conversion element that is provided between the fourth reflection layer and the laser medium, and causes a phase difference for light in vibration directions orthogonal to each other in the light of the second wavelength, and
at least one of a first polarization control element or a second polarization control element that is provided between the first reflection layer and the fourth reflection layer, and controls polarization of the light of the first wavelength or the light of the second wavelength, and
the optical axis of the laminated semiconductor layer, an optical axis of the laser medium, and optical axes of the first polarization conversion element, the second polarization conversion element, and the first polarization control element or the second polarization control element are coaxially arranged.
